(19) United States
(12) Patent Application Publication
(10) Pub. No.: US 2015/0303038 A1
(43) Pub. Date: Oct. 22, 2015

(54) Non-Contact Physical Etching System

(71) Applicant: Zavtrod Innovation Corporation, Hsinchu City (TW)

(72) Inventors: CHENG-WEI YANG, Hsinchu City (TW); VLADIMIR SERGEEVICH SUKHOMLINOV, Leningrad Region (RU)

(21) Appl. No.: 14/643,033

(22) Filed: Mar. 10, 2015

(30) Foreign Application Priority Data
Apr. 17, 2014 (TW) 103114094

(51) Int. Cl. H01J 37/32; H01L 21/67

(52) U.S. Cl. CPC H01J 37/32623; H01J 37/32192; H01J 37/32669; H01J 37/32733; H01L 21/67069

(57) ABSTRACT

The present invention provides a non-contact physical etching system mainly consisting of a main body, a hollow chamber, a plasma generating device, a first mask, and a target carrying platform. Particularly, this non-contact physical etching system can be used for executing a non-contact etching process to a target put on the target carrying platform, without using any lithography processes. Moreover, when the non-contact etching process is operated, the plasma in the hollow chamber would produce a spontaneous electric field near the surface of the first mask for maintaining the electrical neutrality thereof; therefore, by the action of the spontaneous electric field perpendicular to the surface of the first mask, the charged ions in the plasma would be accelerated and then pass through at least one first pattern formed on the first mask, such that the charged ions would etch or cut the target by way of bombarding the target.

### BACKGROUND OF THE INVENTION

1. Field of the Invention

The present invention relates to the technology field of plasma etching, and more particularly to a non-contact physical etching system.

2. Description of the Prior Art

Etching process is one of important manufacturing procedures for the planar fabrication of the chips with integrated circuits and some micro-electromechanical products. Etching technologies does well known be divided to dry etch and wet etch. Please refer to FIG. 6, there is shown a schematic diagram of a conventional wet etching process. In the diagram (a) of FIG. 6, a photoresist agent is coated onto a material layer 12′ formed on a substrate 11′ for forming a photoresist layer 13′ on the material layer 12′ in order to further process the material layer 12′ to a define layer. Next, in the diagram (b) of FIG. 6, the formed photoresist layer 13′ is subsequently treated with a lithography process, such that the portion of the material layer 12′ do not need to be etched is covered by photoresist layer 13′. Eventually, as the diagram (c) of FIG. 6 shows, the material layer 12′ is therefore process to the define layer having at least one specific pattern after a wet etching procedure is carried out.

It is well known that, the most important feature of the wet etch is the high selectivity performed by the used wet agent on the material under etching. However, the occurrence of undercut resulted from isotropic etching has became the primary drawback of the wet etch technology and the main cause for the wet etch technology unable to be applied in the etching procedure with the requirement of high narrow linewidth (<0.35 μm).

Differing from the wet etch, the dry etch is usually represented by plasma etch. Please refer to FIG. 7, which illustrates a schematic framework view of a conventional plasma etching apparatus. As shown in FIG. 7, the conventional plasma etching apparatus mainly consists of: a reaction chamber 2′, an upper electrode plate 21′, a lower electrode plate 22′, at least one gas inputting pipe 23′, and an exhaust pipe 24′. When operating the plasma etching apparatus to carry out a reactive ion etching process, an etch gas is inputted into the reaction chamber 2′ via the gas inputting pipe 23′, so as to be dissociated to charged ions by the plasma 3′. Furthermore, the ions of etch gas would be accelerated by applying a differential voltage between the upper electrode plate 21′ and the lower electrode plate 21′, and then the ions of etch gas would attack the target 4′ disposed in the reaction chamber 2′. Moreover, when the target 4′ is impacted by the accelerated ions, the etch gas would simultaneously chemically reacted with the target's surface. So that, from the above descriptions, it is able to understand that the physical and chemical etching technologies are both used in the conventional plasma etching apparatus for completing the reactive ion etching process.

Herein, it needs to further explain that at least one chemical solution is used for carrying out the isotropic etching of the wet etching process, and at least one chemical gas and plasma ions are applied in dry etching process for complete the anisotropic etching. Therefore, it is clearly that the chemical etching products are necessary to the conventional wet and dry etching processes; so that, the waste treatment of the chemical etching products has became an important issue. Moreover, because the chemical etching products are used in the conventional wet and dry etching processes, the said wet and dry etching technologies cannot be applied to carry out the etch process of biomartials, medical substrates (for example, blood glucose test strip), and organic materials.

Besides, although some advanced etching technologies including electron beam etch, focused ion beam (FIB) etch and excimer laser etch have been entirely developed, the currently-used electron beam etching apparatus, FIB etching apparatus and excimer laser etching apparatus have an identical drawback of being unable to be applied to achieve mass production etching process. Moreover, another drawback of the laser etching apparatus is that its etching accuracy is limited to 10 μm. Opposite to the laser etching apparatus, the beam etching apparatus have another drawback of over expensive vacuum equipment.

Accordingly, in view of the conventional plasma etching apparatus, electron beam etching apparatus, FIB etching apparatus, and excimer laser etching apparatus still include shortcomings and drawbacks, the inventor of the present application has made great efforts to make inventive research thereon and eventually provided a non-contact physical etching system.

### SUMMARY OF THE INVENTION

The primary objective of the present invention is to provide a non-contact physical etching system mainly consisting of a main body, a hollow chamber, a plasma generating device, a first mask, and a target carrying platform. Differing from the conventional plasma etching apparatus, this non-contact physical etching system can be used for executing a non-contact etching process to a target put on the target carrying platform, without treating the target with using any lithography processes in advance. Moreover, when the non-contact etching process is operated, the plasma in the hollow chamber would produce a spontaneous electric field near the surface of the first mask for maintaining the electrical neutrality thereof; therefore, by the action of the spontaneous electric field perpendicular to the surface of the first mask, the charged ions in the plasma would be accelerated and then pass through at least one first pattern formed on the first mask, such that the charged ions would etch or cut the target by way of bombarding the target. For the non-contact physical etching system provided by the present invention carrying out the etching process by purely-physical way, it is sure that the non-contact physical etching system can also be applied to complete the etch process of biomartials, medical substrates (for example, blood glucose test strip), and organic materials.

Accordingly, in order to achieve the primary objective of the present invention, the inventor of the present invention provides a non-contact physical etching system, comprising:

a main body, having a first chamber and a second chamber isolated to each other by a partition member; wherein the first chamber and the second chamber are used as a plasma supplying chamber and a plasma etching chamber, respectively;

a hollow chamber, deposed on the partition member for simultaneously pass through the first chamber and the second chamber;

a working gas supplying device, connected to the main body, and used for inputting a working gas to the main body, so as to make the working gas be transformed to a first portion of the hollow chamber located in the first chamber;

a first mask, disposed in the second chamber and connected to the hollow chamber for shielding a second portion of the hollow chamber located in the second chamber, such that the plasma formed in the first portion of the hollow chamber can be avoided from directly moving into the second chamber; wherein the first mask is also used as a spontaneous electric field triggering member; and

a target carrying platform, disposed in the second chamber and opposite to the first mask;

wherein the plasma in the first portion of the hollow chamber would produce a spontaneous electric field near the surface of the first mask for maintaining the electrical neutrality thereof; moreover, by the action of the spontaneous electric field perpendicular to the surface of the first mask, a plurality of charged ions in the plasma are accelerated and then pass through at least one first pattern formed on the first mask, such that the charged ions would etch or cut a target put on the target carrying platform by way of bombarding the target.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1A is a first framework view of a non-contact physical etching system according to the present invention;

FIG. 1B is a is a second framework view of a non-contact physical etching system according to the present invention;

FIG. 2 shows a framework diagram of a plasma generating device;

FIG. 3 illustrates schematic diagrams of a first mask and a second mask;

FIG. 4 shows an application diagram of the non-contact physical etching system;

FIG. 5 is a schematic framework view of an extensional embodiment for the non-contact physical etching system;

FIG. 6 shows a schematic diagram of a conventional wet etching process; and

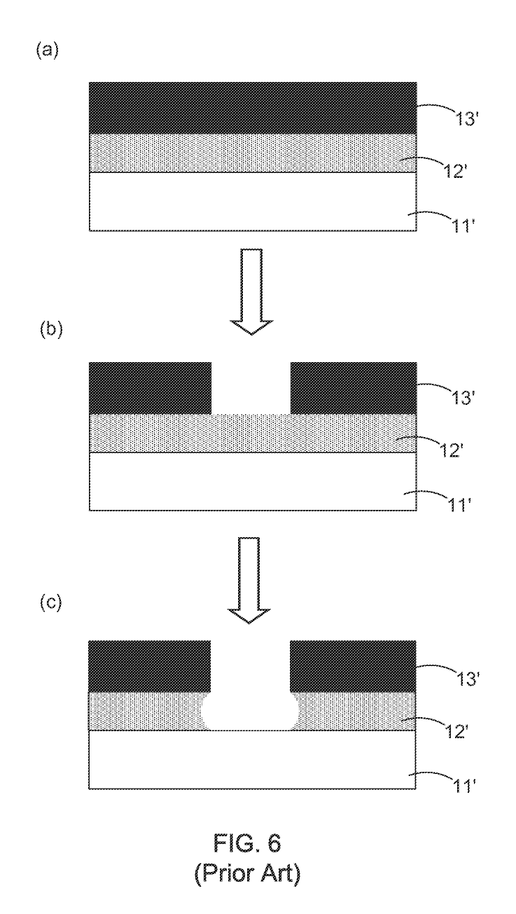

FIG. 7 is a schematic framework view of a conventional plasma etching apparatus.

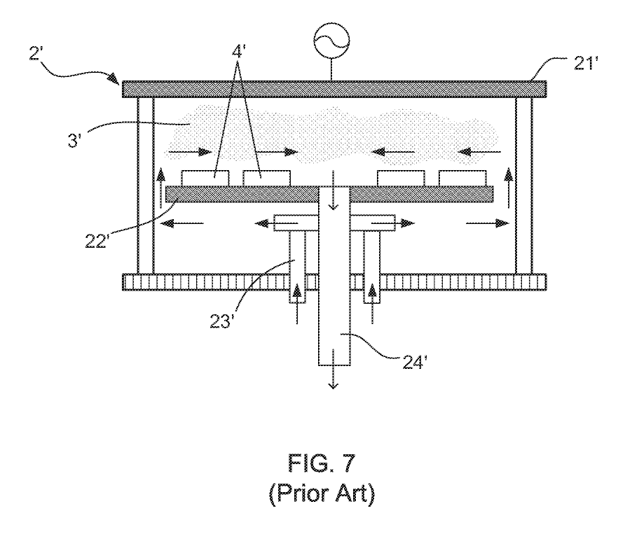

### DETAILED DESCRIPTION OF THE PREFERRED EMBODIMENTS

To more clearly describe a non-contact physical etching system according to the present invention, embodiments of the present invention will be described in detail with reference to the attached drawings hereinafter.

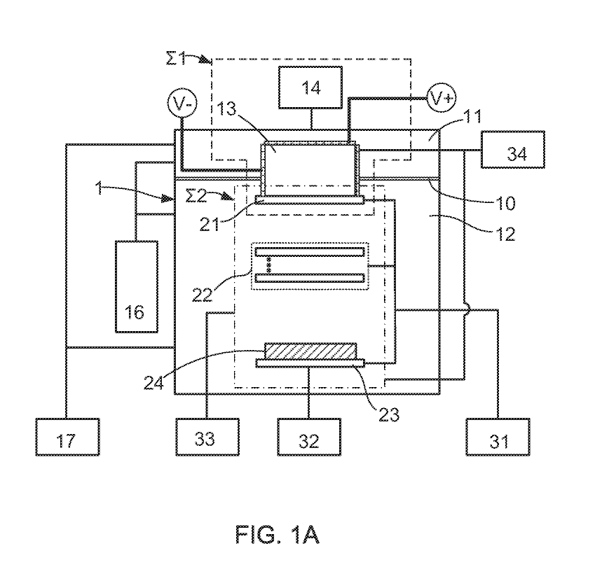

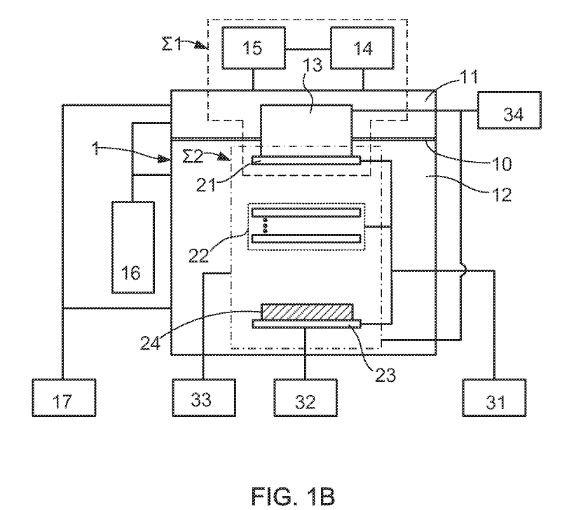

Please simultaneously refer to FIG. 1A, there is shown a first framework view for the non-contact physical etching system according to the present invention. As shown in FIG. 1A, the non-contact physical etching system mainly consists of: a main body 1, a hollow chamber 13 and a working gas supplying device 14. In the present invention, a partition member 10 is disposed in the main body 1 for separating the main body 1 to a first chamber 11 and a second chamber 12, wherein the first chamber 11 and the second chamber 12 are used as a plasma supplying chamber and a plasma etching chamber, respectively. Moreover, the hollow chamber 13 having an inlet opening and an outlet opening is deposed on the partition member 10 for simultaneously pass through the first chamber 11 and the second chamber 12. Besides, the working gas supplying device 14 is connected to the main body 1 for inputting a working gas into the hollow chamber 13 through the inlet opening.

As FIG. 1A shows, an anode plate is disposed on the inlet opening for connected with an anode voltage V+; and oppositely, the hollow chamber 13 is connected with an cathode voltage V−. From above descriptions, it is able to understand that the said hollow chamber 13 is taken as a hollow cathode tube in this non-contact physical etching system. Thus, when the applied anode voltage V+ is greater than the applied cathode voltage V−, the hollow cathode discharge is produced in the hollow chamber 13, such that the working gas inputted into the hollow chamber 13 would be transformed to plasma by the hollow cathode discharge. Therefore, the plasma would further flow into the second chamber 12 (i.e., plasma etching chamber) through the outlet opening of the hollow chamber 13.

Continuously, please refer to FIG. 1B, where a second framework for the non-contact physical etching system is illustrated. In the second framework of the non-contact physical etching system, a plasma generating device 15 is connected to the main body 1 and the working gas supplying device 14, such that the working gas supplying device 14 is able to supply the working gas to the plasma generating device 15, and then the plasma generating device 15 would transform the working gas to the plasma. Therefore, the plasma would be inputted into the hollow chamber 13 by the plasma generating device 15.

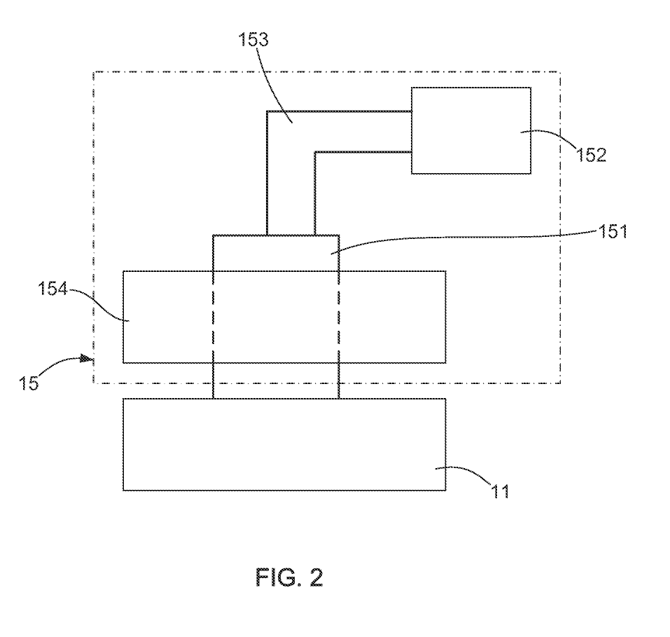

Please simultaneously refer to FIG. 2, there is shown a framework diagram of the plasma generating device 15. As shown in FIG. 2, the plasma generating device 15 is constituted by a reaction chamber 151, a microwave generator 152 and a magnetic module 154, wherein the reaction chamber 151 is communicated with the first chamber 11, and the microwave generator 152 is connected to the reaction chamber 151 through a wave guide tube 153 for inputting a microwave into the reaction chamber 151. In addition, the magnetic module 154 is connected to the reaction chamber 151 for forming a magnetic field in the reaction chamber 151. In the second framework of the non-contact physical etching system, the working gas inputted into the reaction chamber 151 is transformed to the plasma by the action of the microwave and the magnetic field; moreover, based on a frequency match occurring between the microwave and the magnetic field, an electron cyclotron resonance would be produced in the reaction chamber 151 for largely enhancing the concentration of the plasma.

As shown in FIG. 1A and FIG. 1B, the first mask 21 is disposed in the second chamber 12 and opposite to the target carrying platform 23, and the first mask 21 is connected to the hollow chamber 13 for shielding the outlet opening. In the present invention, the first mask 21 is particularly used as a spontaneous electric field triggering member for the plasma in the hollow chamber 13. In addition, by operating an air pressure maintaining device 16 connected to the first chamber 11 and the second chamber 12, the air in the first chamber 11 and the second chamber 12 can be pumping out so as to keep the atmosphere pressure in the first chamber 11 and the second chamber 12 to a first air pressure and a second pressure, respectively.

Herein, it needs to stress that, the first technology feature of the non-contact physical etching system is that, the plasma in the hollow chamber 13 would produce a spontaneous electric field near the surface of the first mask 21 for maintaining the electrical neutrality thereof. So that, by the action of the spontaneous electric field perpendicular to the surface of the first mask 21, a plurality of charged ions in the plasma are accelerated and then pass through at least one first pattern formed on the first mask 21, such that the charged ions would etch or cut a target 24 put on the target carrying platform 23 by way of bombarding the target 24.

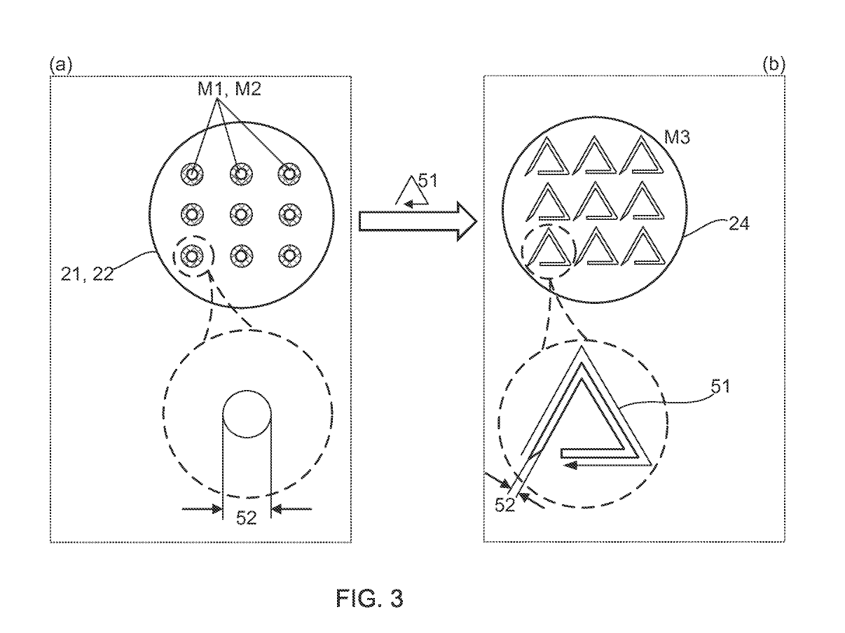

Continuously referring to FIG. 1A and FIG. 1B, and please simultaneously refer to FIG. 3, where the schematic diagrams for a first mask 21 and a second mask 22 are illustrate. In order to avoid the charged ions in the plasma from laterally spread, at least one second mask 22 is disposed in the second chamber 22 and locates between the first mask 21 and the target 24. From FIG. 3, it is able to know that the first pattern M1 formed on the first mask 21 is consisted of at least one aperture 52 or a plurality of aperture s 52; the same to first pattern M1, a second pattern M2 formed on the second mask 22 is consisted of at least one aperture 52 or a plurality of apertures 52. By the disposing of the second mask 22, the charged ions passing through the first pattern M1 are able to further pass through the second pattern M2 on the second mask 22, such that the charged ions are prevented from laterally spread so as to bombard the target 24 straightly and precisely. Another way to reduce the lateral spread of the charged ions is adding one magnetic device into the non-contact physical etching system. As shown in FIG. 1A and FIG. 1B, the added magnetic device 33 is connected to the second chamber 12 for producing a magnetic field in the second chamber 12, such that the charged ions can be avoided from laterally spread based on the action of the a magnetic field.

Moreover, it needs to further explain that, the first pattern M1 (i.e., the aperture 52) formed on the non-metal first mask 21 is enclosed by a metal material in order to facilitate the spontaneous electric field be produced near the surface of the first mask 21. Moreover, in other practicable application, the first mask 21 can also be made of metal materials and subsequently being formed with a non-metal layer thereon. Wherein the said non-metal layer is consisted of at least one third pattern corresponding to the first pattern M1, and the area of the third pattern is designed to be greater than the first pattern M1, so as to make the first pattern M1 be enclosed by the third pattern.

From the diagram (a) depicted by FIG. 3, it is able to know that the basic unit of the first pattern M1 is one aperture 52, and a plurality of apertures 52 constitute a specific pattern of the first pattern M1 on the first mask 21. The same to the first mask 21, the basic unit of the second pattern M2 is one aperture 52, and a plurality of apertures 52 constitute a specific pattern of the second pattern M2 on the second mask 22. As shown in FIG. 3, the said specific pattern of the first pattern M1 and the second pattern M2 can be an aperture array, wherein each of the plurality of the apertures 52 have an identical aperture size.

The second technical feature of the non-contact physical etching system provided by the present invention is that, this non-contact physical etching system can be operated to treat the target 24 put on the target carrying platform 23 with a movable-type etching process by using the first mask 21 and the second mask 22. The said movable-type etching process is illustrated to diagram (b) in FIG. 3. As the diagram (b) of FIG. 3 shows, when the target 24 is treated with an etching process, engineers are able to operate a platform moving device 32 to drive the target carrying platform 23 make motion along a specific moving path 51, such that an etched pattern M3 corresponding to the moving path 51 would be therefore formed on the target 24. As shown in the diagram (b) of FIG. 3, the width of the etched pattern M3 is the same to the aperture size of the aperture 52; that is, as long as the aperture size of the aperture 52 and the moving path 51 are properly set, it is going to carry out any etched patterns with different widths on the target 24 through the movable-type etching process by using this non-contact physical etching system.

Besides, the aforesaid first pattern M1 on the first mask 21 can also be constituted by at least one first string-shaped aperture or a plurality of string-shaped apertures. The same to the first mask 21, the second pattern M2 on the second mask 22 can also consist of at least one second string-shaped aperture or a plurality of second string-shaped apertures. Furthermore, a dot-shaped aperture can be formed by intercrossing any two first string-shaped apertures (or second string-shaped apertures), such that the charged ions in the plasma are able to pass through the first pattern M1 (and second pattern M2) represented by the dot-shaped aperture, so as to bombard the target 24 for completing a etching process or a pattern-making process.

Inheriting to above descriptions, the etching plasma would etch the target 24 according to an intersection pattern between the first pattern M1 and the second pattern M2 when executing the target's 24 etching process via the first mask 21 having the first pattern M1 and the second mask 22 having the second pattern M2. For instance, if the first pattern M1 is identical to the second pattern M2, the said intersection pattern will be the same to the first pattern M1 and the second pattern M2. Moreover, when the first pattern M1 is different from the second pattern M2, a plurality of slit apertures formed by way of oppositely crossing the first pattern M1 and the second pattern M2 are able to be defined as a plurality of intersection points. Furthermore, a plurality of tiny slit apertures can be formed by crisscrossing the first pattern M1 and the second pattern M2. In addition, the first pattern M1 and the second pattern M2 can also be both represented by a slit aperture array with narrow slit width. In which, the intersection pattern between the first pattern M1 and the second pattern M2 will be an aperture array if the directionally-included angles between the slit apertures are designed to be close to 90°. That is, it is going to carry out any etched patterns with different widths on the target 24 through the intersection pattern of the first pattern M1 and the second pattern M2 by using this non-contact physical etching system.

In addition, for making the charged ions in the plasma have enough etching energy, a bias device 31 is added into the non-contact physical etching system. As shown in FIG. 1A and FIG. 1B, the bias device 31 is connected to the first mask 21, the at least one second mask 22 and the target carrying platform 23, and used for forming an electric filed between the first mask 21 and the target carrying platform 23, the second mask 22 and the target carrying platform 23, or any two second mask 22. Thus, by the action of the accelerating electric filed, the charged ions in the plasma would get enough etching energy so as to etch the target 24 by way of bombarding the target 24. Moreover, when the sad etching depth is great than or equal to the target's thickness, the target 24′ would be cut or penetrated by the plasma's bombarding ions.

Furthermore, as shown in FIG. 1A and FIG. 1B, an auxiliary device 17 is connected to the main body 1 for measuring a temperature parameter and a plasma parameter. Once the engineers find the working temperature of the main body 1 is too high from the auxiliary device 17, the engineers are going to operate a cooling device 34 connected with the main body 1 for cooling the hollow chamber 13, the target carrying platform 23, and/or the target 24. In addition, when practically applying this non-contact physical system, an alignment device can be used for adjusting a position relationship between the first mask 21, the second mask 22 and the target carrying platform 23, so as to ensure the position relationship be able to meet the requirement of the etching process.

Herein, it needs to further explain that, the mark of Σ1 shown in FIG. 1A and FIG. 1B is indicated to a first working environment, and the said first working environment Σ1 means a plasma producing environment. That is, the first working environment Σ1 consists of the first chamber 11, the hollow chamber 13, the working gas supplying device 14, and the plasma generating device 15. Moreover, above descriptions imply that the first chamber 11, the hollow chamber 13, the working gas supplying device 14, and the plasma generating device 15 can be integrated to one single apparatus for producing and supplying etching plasma. Opposite to the first working environment Σ1, a second working environment Σ2 shown in FIG. 1A and FIG. 1B means a specific environment for executing plasma etching process. That is, the second working environment Σ2 is consisted of the second chamber 12, the first mask 21, the second mask 22, and the target carrying platform 23. Moreover, above descriptions also imply that the second chamber 12, the first mask 21, the second mask 22, and the target carrying platform 23 can be integrated to another one single apparatus for executing the plasma etching process.

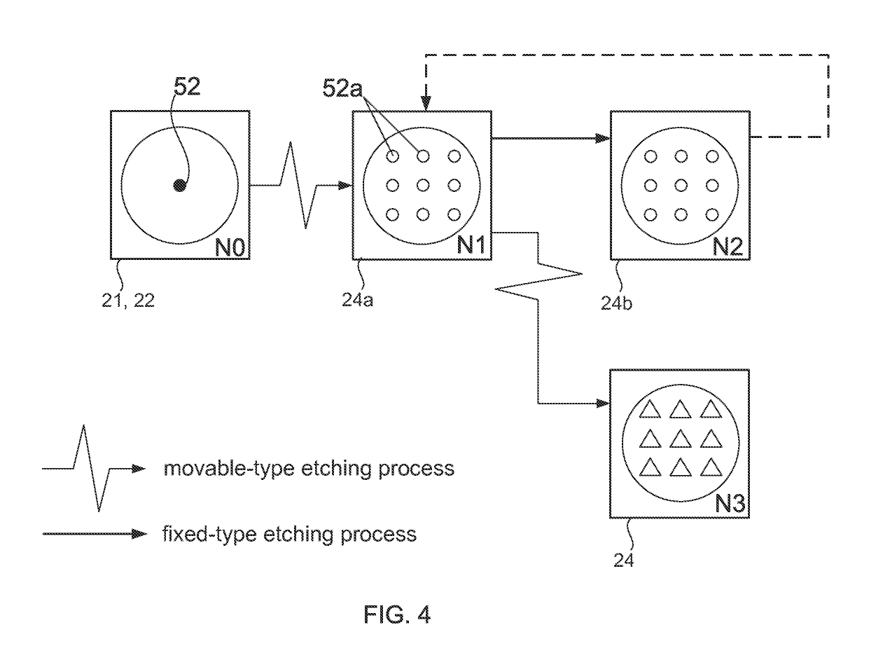

Continuously referring to FIG. 4, there is shown an application diagram of the non-contact physical etching system. From FIG. 4, it is able to know that the non-contact physical etching system can be used to complete a movable-type etching process and/or a fixed-type etching process. Before detailedly introducing the technology feature of the movable-type etching process and the fixed-type etching process, it needs to explain that the first mask 21 (and/or the second mask 22) is provided with a base pattern N0 thereon, wherein the said base pattern N0 can be a single aperture 52. Therefore, a first base mask 24a having a first etched pattern N2 can be fabricated after treating the target 24 with the movable-type etching process by using the first mask 21 (and the second mask 22). As shown in FIG. 4, the said first etched pattern N2 consists of a plurality of apertures 52a.

Furthermore, a copied mask 24b of the first base mask 24a can be manufacture by executing the fixed-type etching process onto the target 24 by using the first base mask 24a. As FIG. 4 shows, the copied mask 24b has a second etched pattern N2 identical to the first etched pattern N1 on the first base mask 24a. In addition, it is able to further form a third etched pattern N3 on the target 24 through the first base mask 24a by using the movable-type etching process. In brief, as long as the aperture size of the aperture 52 and the moving path 51 are properly set, it is going to carry out any etched patterns with given widths on the target 24 through the movable-type etching process by using this non-contact physical etching system. Moreover, the engineers are able to make the copied masks of the first mask 21 and the second mask 22 through the fixe-type etching process, without outsourced manufacturing or purchase.

Therefore, through above descriptions, the non-contact physical etching system proposed by the present invention has been introduced completely and clearly; in summary, the present invention includes the advantages of:
(1) Differing from conventional wet etching apparatus or dry etching apparatus, the present invention proposes a non-contact physical etching system mainly constituted by a main body 1, a hollow chamber 13, a working gas supplying device 14, a plasma generating device 15, a first mask 21, and a target carrying platform 23. Particularly, this non-contact physical etching system can be used for completing the etching process to the target 24 put on the target carrying platform 23, without treating the target 24 with using any lithography processes in advance.
(2) Moreover, when the non-contact etching process is operated, the plasma in the hollow chamber 13 would produce a spontaneous electric field near the surface of the first mask 21 for maintaining the electrical neutrality thereof; therefore, by the action of the spontaneous electric field perpendicular to the surface of the first mask 21, the charged ions in the plasma would be accelerated and then pass through at least one first pattern M1 formed on the first mask 21, such that the charged ions would etch or cut the target 24 by way of bombarding the target 24. For the non-contact physical etching system provided by the present invention carrying out the etching process by purely-physical way, it is sure that this non-contact physical etching system can also be applied to complete the etch process of biomartials, medical substrates (for example, blood glucose test strip), and organic materials.
(3) Moreover, in contrast to the currently-used electron beam etching apparatus, FIB etching apparatus and excimer laser etching apparatus have an identical drawback of being unable to be applied to achieve large scale etching process, this non-contact physical etching system is going to treat the target 24 with a large-scale etching process as long as the first mask 21 and the second mask 22 have properly set.

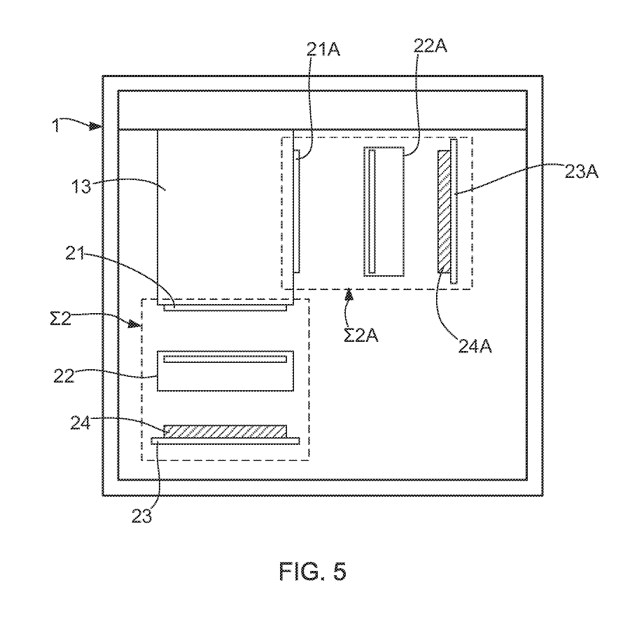

Herein, an expansion-type embodiment for the non-contact physical etching system will be introduced in following paragraphs. Please refer to FIG. 5, where a schematic framework view of the extensional embodiment for the non-contact physical etching system is shown. In the extensional embodiment, hollow chamber 13 disposed in the main body 1 is provided with two outlet openings, and the two outlet openings are shielded by one first mask 21 and one first additional mask 21A. Moreover, the second mask 22 is also disposed between the target carrying platform 23 and the first mask 21. In addition, an additional target carrying platform 23A is disposed in the main body 1 and opposite to the first additional mask 21A, and a second additional mask 22A is disposed between the additional target carrying platform 23A and the second additional mask 22A.

Although the exemplary embodiment for the non-contact physical etching system depicted by FIG. 1A and FIG. 1B merely includes one second working environment Σ2 (i.e., the plasma etching environment), that is not used for limiting the numbers of the plasma etching environments. In other possible applications, it can also disposed two or more plasma etching environments; for example, the expansion-type embodiment for the non-contact physical etching system depicted by FIG. 5 is disposed with two plasma etching environments, i.e., one second working environment Σ2 and one second additionally-working environment Σ2A.

The above description is made on embodiments of the present invention. However, the embodiments are not intended to limit scope of the present invention, and all equivalent implementations or alterations within the spirit of the present invention still fall within the scope of the present invention.

What is claimed is:

1. A non-contact physical etching system, comprising:
a main body, having a first chamber and a second chamber isolated to each other by a partition member; wherein the first chamber and the second chamber are used as a plasma supplying chamber and a plasma etching chamber, respectively;
a hollow chamber, being deposed on the partition member for simultaneously pass through the first chamber and the second chamber;
a working gas supplying device, being connected to the main body, and used for inputting a working gas to the main body, so as to make the working gas be transformed to a first portion of the hollow chamber located in the first chamber;
a first mask, being disposed in the second chamber and connected to the hollow chamber for shielding a second portion of the hollow chamber locating in the second chamber, such that the plasma formed in the first portion of the hollow chamber can be avoided from directly moving into the second chamber; wherein the first mask is also used as a spontaneous electric field triggering member; and
a target carrying platform, being disposed in the second chamber and opposite to the first mask;
wherein the plasma in the first portion of the hollow chamber would produce a spontaneous electric field near the surface of the first mask for maintaining the electrical neutrality thereof; therefore, by the action of the spontaneous electric field perpendicular to the surface of the first mask, a plurality of charged ions in the plasma being accelerated and then pass through at least one first pattern formed on the first mask, such that the charged ions would etch or cut a target put on the target carrying platform by way of bombarding the target.

2. The non-contact physical etching system of claim 1, wherein the hollow chamber has an inlet opening and an outlet opening; moreover, the working gas being inputted into the hollow chamber via the inlet opening, and the first mask shielding the outlet opening.

3. The non-contact physical etching system of claim 1, further comprising a plasma generating device connected to the working gas supplying device and the main body; wherein the working gas supplying device is able to supply the working gas to the plasma generating device, and then the plasma generating device would transform the working gas to the plasma; therefore, the plasma being inputted into the hollow chamber by the plasma generating device.

4. The non-contact physical etching system of claim 1, further comprising at least one second mask, being disposed in the second chamber and locating between the first mask and the target; therefore, the charged ions passing through the at least one first pattern are able to further pass through at least one second pattern formed on the second mask, such that the charged ions are prevented from laterally spread so as to bombard the target straightly and precisely.

5. The non-contact physical etching system of claim 1, further comprising a cooling device, being connected to the main body and used for cooling the hollow chamber, the target carrying platform and the target.

6. The non-contact physical etching system of claim 1, wherein the first pattern on the first mask consists of at least one first aperture or a plurality of first apertures, and the second pattern on the second mask consists of at least one second aperture or a plurality of apertures.

7. The non-contact physical etching system of claim 1, wherein the first pattern on the first mask consists of at least one first string-shaped aperture or a plurality of string-shaped apertures, and the second pattern on the second mask consists of at least one second string-shaped aperture or a plurality of second string-shaped apertures.

8. The non-contact physical etching system of claim 1, further comprising a magnetic device connected to the second chamber, wherein the charged ions can be avoided from laterally spread after a magnetic field provided by the magnetic device is applied to the second chamber.

9. The non-contact physical etching system of claim 1, further comprising an air pressure maintaining device, being connected to the first chamber and the second chamber, and used for pumping the air out of the first chamber and the second chamber, so as to keep the atmosphere pressure in the first chamber and the second chamber to a first air pressure and a second pressure, respectively.

10. The non-contact physical etching system of claim 1, further comprising an auxiliary device, being connected to the main body for measuring a temperature parameter and a plasma parameter.

11. The non-contact physical etching system of claim 2, wherein an anode plate is disposed on the inlet opening for being connected with an anode voltage; and oppositely, the hollow chamber being connected with an cathode voltage.

12. The non-contact physical etching system of claim 3, wherein the plasma generating device comprises:
a reaction chamber, being communicated with the first chamber;
a microwave generator, being connected to the reaction chamber through a wave guide tube, used for inputting a microwave into the reaction chamber; and
a magnetic module, being connected to the reaction chamber for forming a magnetic field in the reaction chamber;
wherein the working gas inputted into the reaction chamber is transformed to the plasma by the action of the microwave and the magnetic field; moreover, based on a frequency match occurring between the microwave and the magnetic field, an electron cyclotron resonance would be produced in the reaction chamber for largely enhancing the concentration of the plasma.

13. The non-contact physical etching system of claim 5, further comprising a platform moving device, being connected to the target carrying platform, and used for relatively moving the target carrying platform against the fixed first mask or the second mask.

14. The non-contact physical etching system of claim 5, further comprising a bias device connected to the first mask, the at least one second mask and the target carrying platform; wherein the bias device is used for forming an electric filed between the first mask and the target carrying platform, the second mask and the target carrying platform, or any two second mask, so as to accelerate the charged ions.

15. The non-contact physical etching system of claim 7, wherein a dot-shaped aperture can be further formed by intercrossing any two first string-shaped apertures, such that the charged ions in the plasma are able to pass through the first pattern represented by the dot-shaped aperture, so as to bombard the target for carrying out a etching process or a pattern-making process.

16. The non-contact physical etching system of claim 7, wherein a dot-shaped aperture can be further formed by intercrossing any two second string-shaped apertures, such that the charged ions in the plasma are able to pass through the second pattern represented by the dot-shaped aperture, so as to bombard the target for carrying out a etching process or a pattern-making process.

17. The non-contact physical etching system of claim 8, wherein the second air pressure is smaller than the first air pressure.
